(19) United States
(12) Patent Application Publication
(10) Pub. No.: US 2017/0045567 A1
(43) Pub. Date: Feb. 16, 2017

(54) MONITORING METHOD AND SYSTEM OF ARRESTER APPLIED TO SMART SUBSTATION

(71) Applicants: XJ GROUP CORPORATION, Xuchang (CN); XJ ELECTRIC CO.,LTD, Xuchang (CN); XUCHANG XJ SOFTWARE TECHNOLOGIES LTD, Xuchang (CN); STATE GRID CORPORATION OF CHINA, Beijing (CN)

(72) Inventors: Mingchao Yong, Xuchang (CN); Wumin Liang, Xuchang (CN); Guanghui Lu, Xuchang (CN); Weijie Wang, Xuchang (CN); Shuibin Zhou, Xuchang (CN); Guohui Zeng, Xuchang (CN); Dongwu Gong, Xuchang (CN); Yishi Zhuang, Xuchang (CN); Xia Lv, Xuchang (CN); Fang Yang, Xuchang (CN); Sheng Lu, Xuchang (CN); Zhong Zhou, Xuchang (CN); Jiqing Mu, Xuchang (CN); Xu Guo, Xuchang (CN); Zhicheng Wang, Xuchang (CN)

(73) Assignees: XJ GROUP CORPORATION; XJ ELECTRIC CO.,LTD

(21) Appl. No.: 15/076,660

(22) Filed: Mar. 22, 2016

(30) Foreign Application Priority Data
Aug. 10, 2015 (CN) 201510485726.3

(51) Int. Cl. G01R 31/02; G01R 31/327; H02H 9/04

(52) U.S. Cl. CPC G01R 31/02; H02H 9/04; G01R 31/327

(57) ABSTRACT

The present invention relates to a monitoring method and system of arrester applied to smart substation. The monitoring method of arrester applied to smart substation includes following steps: 1) getting original sample value of the arrester leakage current, 2) getting resample values of the original sample values of leakage current and SV voltage signals, 3) getting the amplitude and the phase values of the resample values of the leakage current and the SV voltage signals by Fourier transforming, 4) calculating angles between the resample values of the leakage current and the SV voltage signals according to the phase values of the resample values of the leakage current and the SV voltage signals, and calculating value of resistive current with the method of fundamental wave projection, 5) getting value of resistive current after medium filtered by medium filtering the value of resistive current, making a comparison of the value of resistive current after medium filtered and setting threshold value, and forewarning timely when the value of resistive current after medium filtered exceeds the setting threshold value. The monitoring system of arrester applied to smart substation comprises collecting unit, data processing unit and merge unit. The present invention, that the monitoring method of arrester applied to smart substation, could reduce the influence of the electronic interference on the system and raise the monitor accuracy of the faults of the arrester.

### FIELD OF INVENTION

The present invention relates, in general, to smart arrester, and, more particularly, to a monitoring method and system of arrester applied to smart substation.

### BACKGROUND

Zinc oxide arrester, normal operation of which is the important guarantee for the safe and reliable travel of the other equipments, is an important electric element of power system. For online monitoring and timely diagnosing of zinc oxide arrester, it can timely discover and clear the potential fault of arrester effectively, and ensure the safe and stable operation of arrester or even the whole power system.

Leakage current, resistive current, which is the key characteristic of deterioration degree of arrester facility, and capacitative current are the main monitor parameters of the zinc oxide arrester. As a component of leakage current, for the resistive current it would need to collect the leakage current and the bus voltage at the same time. Now the most common scheme adopted is: voltage acquisition device is used to gather voltage signal of the second side of PT, synchronize resampling all of leakage current sensors of system by synchronized pulse, and transfer value of bus voltage phasor to various leakage current collecting units in the manner of private protocol. The leakage current collecting units are used to calculate total leakage current phasor, receive voltage phasor after been synchronized collected and calculated, and calculate the monitor parameters such as the resistive current. Since experiment and popularization of smart and new general smart substation, electric transformer is used more and more generally, and it is the cause of the problem that the existing arrester monitor system can't join into the smart substation. In the meantime, arrester monitoring, transferred in the manner of vector, isn't suitable for application of complex and high-efficiency arithmetic. The communication mode, is usually in the manner of CAN bus, RS485/RS422. etc, not only have the poor anti-interference performance, but also need to increase protocol transform of protocol transformer to meet communication requirement of the smart substation.

So, it is badly needed to improve present monitoring method of arrester, and search a suitable supporting facility of monitoring system of arrester and monitor method for meeting requirement of the construction of smart substation and improving anti-interference performance of the monitoring of arrester.

### SUMMARY OF THE INVENTION

The present invention provides a monitoring method and system of arrester applied to smart substation to solve the problem that the present monitoring system and method of arrester can't match the construction of the smart substation.

In order to solve above technical problems, the present invention, that the monitoring method of arrester applied to smart substation includes following steps:

1) getting original sample values of leakage current of arrester,

2) resample processing the original sample values of leakage current and SV voltage signals transferred from merging unit, and getting resample values of the leakage current and the SV voltage signals respectively,

3) getting amplitude and phase values of the resample values of the leakage current and the SV voltage signals by Fourier transforming about the resample values of the leakage current and the SV voltage signals,

4) calculating angles between the resample values of the leakage current and the SV voltage signals according to the phase values of the resample values of the leakage current and the SV voltage signals, and calculating value of resistive current with the method of fundamental wave projection,

5) getting value of resistive current after medium filtered by Medium filtering the value of resistive current, making a comparison of the value of resistive current after medium filtered and setting threshold value, and forewarning timely when the value of resistive current after medium filtered exceeds the setting threshold value.

Resample processing at step 2), it is used to resample at resample time tᵣₖ with Lagrange parabola interpolation. Computational formulas of the leakage current Iᵣₖ and the voltage signals 1Vᵣₖ are:

$$\{ \begin{matrix}{I}_{rk} = {\sum }_{i = 0}^{2} ( {I}_{i} {{Π}^{2}}_{{j = 0}_{j \neq i}} \frac{{t}_{rk} - {t}_{mj}}{{t}_{mi} - {t}_{mj}} ) \\ {V}_{rk} = {\sum }_{i = 0}^{2} ( {V}_{i} {{Π}^{2}}_{{j = 0}_{j \neq i}} \frac{{t}_{rk} - {t}_{nj}}{{t}_{ni} - {t}_{nj}} )\end{matrix}$$

wherein tₘₖ is sample time of leakage current, tₙₖ is sample time of voltage signal, Iᵢ and Vᵢ are sample values of leakage current and voltage signal at time tₘᵢ and tₙᵢ respectively, and tₘᵢ and tₙᵢ are sample times of sample points before and after the sample time of leakage current tₘₖ and the sample time of voltage signal tₙₖ respectively, herein to 1=0,1,2.

Computational formulas of real and imaginary part information of the resample values of the leakage current and the SV voltage signals through the Fourier transforming are:

The formula of the real part information:

$$Ure = {\sum }_{i = 0}^{N - 1} U [ i ] * Hc [ j ]$$

$$j = Number * i$$

The formula of the imaginary part information:

$$U im = {\sum }_{i = 0}^{N - 1} U [ i ] * Hs [ j ] j = {Number}^{*} i$$

$$Hc [ j ] = \frac{2}{N} * cos \frac{2 ( j + 1 ) π}{N} , j = 0 , 1 , … , N - 1$$

$$Hs [ j ] = \frac{2}{N} * sin \frac{2 ( j + 1 ) π}{N} , j = 0 , 1 , … , N - 1$$

wherein U(i) are sample values of appointed time window which is get from input channel number, forward cycle amount and sample indicator, N is data length, Number is harmonic order, Hc[j] and Hs[j] are filter coefficients by Fourier transforming of whole cycle.

The method of fundamental wave projection at step 4), it is used with interphase compensation fundamental wave projection method, and definite computation process is:

for triphase arrester, it is calculated to get A, B and C amplitude values of the leakage current I_{A1}, I_{B1}, I_{C1} of triphase fundamental wave, and A, B and C amplitude values of the SV voltage signal U_{A1}, U_{B1}, U_{C1} of the triphase fundamental wave, the angles φ_{A1}, φ_{B1}, φ_{C1} between the leakage current values and the SV voltage signal of each phase of the triphase fundamental wave respectively, and angle φ_{AC1} between leakage current value of A phase of the triphase fundamental wave I_{A1} and leakage current value of C phase of the triphase fundamental wave I_{C1}. Bias angle φ=(φ_{AC1}−120)/2, so resistive current value of the A phase fundamental wave I_{RA1}=I_{A1}COS(φ_{A1}+φ), resistive current value of B phase fundamental wave I_{RB1}=I_{B1}COS(φ_{B1}), and resistive current value of the C phase fundamental wave I_{RC1}=I_{C1}COS(φ_{C1}−φ).

Process of the medium filtering at step 5) is: setting slide window with established width and sliding along time sequence, ordering data of the slide window by numeric size, and outputting the values of resistive current after medium filtered which form data sequence after medium filtering.

The monitoring system of arrester applied to smart substation, of the present invention, comprises the collecting unit, data processing unit, and merge unit which transfers the SV voltage signal and communicates with the data processing unit. Wherein the collecting unit is used to get the original sample values of leakage current of the arrester and amount of lighting stroke of the arrester, and frame and transfer the original sample values of leakage current of the arrester. The data processing unit is used to analyze the original sample values of leakage current of the arrester and the Voltage signal to realize the timely diagnosing of the resistive current, and communicate with the collecting unit.

The collecting unit comprises zero flux sensors, rogowski coil mutual inductor, programmable amplifiers, A/D devices, processing circuit of the number of the lighting stroke, and FPGA module.

The data processing unit comprises resample module, compute module of the resistive current, and analyzing and diagnosing module.

The data processing unit also comprises the external communication module making data interaction with integral monitor system of smart substation by fiber interface and in the manner of DL/T860 standard protocol.

The data is transferred on the format of FT3 between the data processing unit and the collecting unit.

The present invention provides a monitoring method and system of arrester applied to smart substation, according to construction of smart substation, which includes: using the SV voltage signal transferred from the merge unit as the synchronize voltage signal, and resample processing the SV voltage signal and the original sample values of leakage current. And the present invention realizes synchronization of voltage and current signals, not only solves the problem of that, it couldn't synchronize the voltage and the current signals during monitoring process of the arrester, but also diagnoses timely after the medium filtering, finds out the interference points, and lowers probability of system misjudgment.

The method of the present invention, which computes the resistive current by using the interphase compensation fundamental projecting method, raises the computed accuracy of resistive current.

Meanwhile, transferring between each part of the system, by the fiber interfaces and based on the standard communication protocol, can reduce influence of electronic interference on system and has enormous field engineering application value.

### BRIEF DESCRIPTION OF THE DRAWING

FIG. 1 a software flow pattern of the arrester monitor method of the present invention,

FIG. 2 a structure drawing of the arrester monitor system of the present invention.

### DETAILED DESCRIPTION

The present invention will be further described hereinafter by referring to the drawings and the examples.

Example of the monitoring method of arrester applied to smart substation

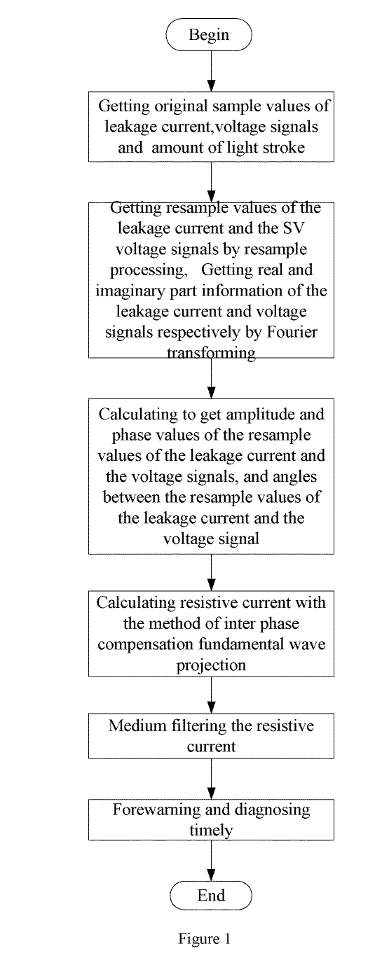

As shown in FIG. 1, the present invention, the monitoring method of arrester applied to smart substation, includes following steps:

1) getting the original sample values of leakage current from the collecting unit,

2) resample processing the original sample values of leakage current and SV voltage signals transferred from merging unit, and getting resample values of the leakage current and the SV voltage signal respectively,

3) getting amplitude and phase values of the resample values of the leakage current and the SV voltage signals by Fourier transforming about the resample values of the leakage current and the SV voltage signal,

4) calculating angles between the resample values of the leakage current and the SV voltage signal according to the phase values of the resample values of the leakage current and the SV voltage signal, and calculating value of resistive current with the method of fundamental wave projection,

5) getting value of resistive current medium filtered by medium filtering the value of resistive current, making a comparison of the value of resistive current after medium filtered and setting threshold value, and forewarning timely when the value of resistive current after medium filtered exceeds the setting threshold value.

The realize process of each step upon will be more detailed described below.

The original sample values of leakage current at step 1), which are 80 sample value signals of each whole cycle wave, are received on the format of FT3.

The voltage signals at step 2), which also are 80 sample value signals of each whole cycle wave, are received by networking mode and transferred from the merge unit on the process level. The detailed realize method of resample process of the received original sample values of leakage current and voltage signals is:

If tₘₖ is sample time of the leakage current, tₙₖ is sample time of the voltage signal, tᵣₖ is resample time. When the original sample values of leakage current and SV voltage signals are calculated with the Lagrange parabola interpolation at the resample time, resample values of 3 resample times, before and after the resample time, must be known, and interval between two neighbor resample times should be equal to about one resample period. Channel electricity values at resample time tᵣ₁, of the original sample values of leakage current and the voltage signal, could be calculated by below formulas:

$$\{ \begin{matrix}{I}_{r 1} = {\sum }_{i = 0}^{2} ( {I}_{i} {{Π}^{2}}_{{j = 0}_{j \neq i}} \frac{{t}_{r 1} - {t}_{mj}}{{t}_{mi} - {t}_{mj}} ) \\ {V}_{r 1} = {\sum }_{i = 0}^{2} ( {V}_{i} {{Π}^{2}}_{{j = 0}_{j \neq i}} \frac{{t}_{r 1} - {t}_{nj}}{{t}_{ni} - {t}_{nj}} )\end{matrix}$$

wherein Iᵢ is original sample electricity value of the leakage current at sample times tₘᵢ and Vᵢ is voltage signal at sample time tₙᵢ.

If there have fixed delay time of the leakage current and the voltage signal, tₘᵢ and tₙᵢ would be calculated by that receive times of the leakage current and the voltage signal minus the fixed delay times of the corresponding collection channel respectively.

In above resample process, according to the fixed delay times of the leakage current and the voltage signals, it is synchronized in the method of interpolation resample for the leakage current and voltage signal. To be other examples, it also could be synchronized in resample method of convolution and so on.

The Fourier transforming at step 3), taking 40 points from 80 points of whole cycle, formulas of filter coefficients in which are as follows:

$$Hc [ i ] = \frac{2}{N} * cos \frac{2 ( i + 1 ) π}{N} , i = 0 , 1 , … , N - 1$$

$$Hs [ i ] = \frac{2}{N} * sin \frac{2 ( i + 1 ) π}{N} , i = 0 , 1 , … , N - 1$$

Wherein U(i), by forwarding U[n−1] in turn, are sample values of the appointed time window which is get from input channel number, forward cycle amount and sample indicator, N is data length.

The formula of the real part information:

$$U re = {\sum }_{i = 0}^{N - 1} U [ i ] * Hc [ j ] j = {Number}^{*} i$$

The formula of the imaginary part information:

$$U im = {\sum }_{i = 0}^{N - 1} U [ i ] * Hs [ j ] j = {Number}^{*} i$$

Wherein Number is number of harmonic order.

Preferably for the method of fundamental wave projection, at step 4) of this example, it is used with interphase compensation fundamental wave projection method, and definite computation process is:

For tripe phase arrester, it is calculated to get A, B and C amplitude values of the leakage current I_{A1}, I_{B1}, I_{C1} of triphase fundamental wave respectively, A, B and C amplitude values of the SV voltage signal U_{A1}, U_{B1}, U_{C1} of the triphase fundamental wave, the angles φ_{A1}, φ_{B1}, φ_{C1} between the leakage current values and the SV voltage signal of each phase of the triphase fundamental wave respectively, and angle φ_{AC1} between leakage current value of A phase of the triphase fundamental wave I_{A1} and leakage current value of C phase of the triphase fundamental wave I_{C1}. Bias angle φ=(φ_{AC1}−120)/2, so resistive current value of the A phase fundamental wave I_{RA1}=I_{A1}COS(φ_{A1}+φ), resistive current value of B phase fundamental wave I_{RB1}=I_{B1}COS(φ_{B1}), and resistive current value of the C phase fundamental wave I_{RC1}=I_{C1}COS(φ_{C1}−φ).

As other examples, it is also used with other fundamental wave projection method to calculate resistive current, and there are lot kinds of fundamental wave projection method, which are not detailed herein.

Process of the medium filtering at step 5) is: Setting slide window with established width and sliding along time sequence, ordering data of the slide window by numeric size, and outputting the values of resistive current after medium filtered which form, another data sequence, one data sequence after medium filtering, Then making a comparison of the value of resistive current after medium filtered and setting threshold value, and forewarning timely when the value of resistive current after medium filtered exceeds the setting threshold value.

Example of the monitoring system of arrester applied to smart substation

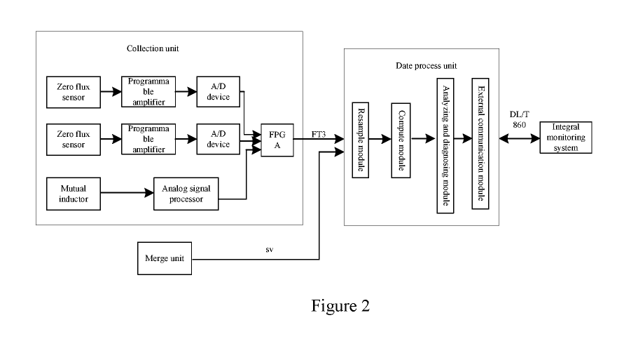

As shown in FIG. 2, the monitoring system of arrester applied to smart substation, suitable for the above monitor method, comprises: the collecting unit, which is used to get the original sample values of leakage current and amount of lighting stroke of the arrester, and frame and transfer the original sample values of leakage current of the arrester, data processing unit and merge unit transferring the SV voltage signal to the data processing unit. The data processing unit is used to resample monitoring data of the arrester, analyze the original sample values of leakage current of the arrester and the Voltage signal to realize timely forewarning and external communicating.

Wherein, the collecting unit comprises zero flux sensors, rogowski coil mutual inductor, programmable amplifiers, A/D devices, processing circuit of the amount of the lighting stroke, and FPGA module. Programmable amplification of leakage current used the zero flux sensors and the programmable amplifiers of trans-impedance, could ensure the high accuracy measure of leakage current signal. Collecting of the amount of light stroke is realized by using self integration rogowski coil to compare with threshold value. Hardware of the collecting unit is FPGA hardware frame, which is used to high speed sample and first treatment of leakage current and voltage signals, and transfer processed 80 sample values of leakage current of each whole cycle wave to the data processing unit on format of FT3.

It is realized by using Power PC processor for the data processing unit. The data processing unit is divided into software platform and application programming part. The sample values of the leakage current and the amount of light stroke, which are transferred from the collection unit on the format of FT3, and the voltage signal transferred from the merge unit on processing level on format of SV are received for the data process unit. After resample processing the original sample values of leakage current and SV voltage signals by resample module, the compute module of resistive current calculates to get amplitude and phase values of the resample values of the leakage current and the SV voltage signals by Fourier transforming about the resample values of the leakage current and voltage signals, angles between the resample values of the leakage current and the voltage signal, and calculates value of resistive current with interphase compensation fundamental wave projection method. Resistive current after medium filtered in slide window is diagnosed timely by analyzing and diagnosing module which evaluates and analyzes about equipment status of the arrester light weightily. External communication module of the data processing unit transfer data processing result by fiber interface and in the manner of DL/T860 standard protocol, and makes data interaction with integral monitoring system of smart substation.

It isn't confined to the described examples provided in above description for the present invention. The basic idea for the present invention is the above general scheme. For general technical staff of the field, it isn't need to put in too much creative work on designing the variant of the modules, formulas and parameters according to the inspiration of the present invention. The change, modification, replacement and variation of the examples, which are not broken away from the theory and the mind of the present invention, still would be dropped into the protected scope of the present invention.

1. A monitoring method of arrester applied to smart substation includes following steps:
1) getting original sample values of leakage current of arrester;
2) getting resample values of the leakage current and the SV voltage signals by resample processing the original sample values of leakage current and SV voltage signals transferred from merging unit respectively;
3) getting amplitude and phase values of the resample values of the leakage current and the SV voltage signals by Fourier transforming about the resample values of the leakage current and the SV voltage signals;
4) calculating angles between the resample values of the leakage current and the SV voltage signals according to the phase values of the resample values of the leakage current and the SV voltage signals, and calculating value of resistive current with the method of fundamental wave projection; and
5) getting value of resistive current after medium filtered by Medium filtering the value of resistive current, making a comparison of the value of resistive current after medium filtered and setting threshold value, and forewarning timely when the value of resistive current after medium filtered exceeds the setting threshold value.

2. The monitoring method of arrester applied to smart substation of claim 1, wherein resample processing at step 2) is used to resample at resample time tᵣₖ with Lagrange parabola interpolation, computational formulas of the leakage current Iᵣₖ and the voltage signals 1Vᵣₖ are:
$$\{ \begin{matrix}{I}_{rk} = {\sum }_{i = 0}^{2} ( {I}_{i} {{Π}^{2}}_{{j = 0}_{j \neq i}} \frac{{t}_{rk} - {t}_{mj}}{{t}_{mi} - {t}_{mj}} ) \\ {V}_{rk} = {\sum }_{i = 0}^{2} ( {V}_{i} {{Π}^{2}}_{{j = 0}_{j \neq i}} \frac{{t}_{rk} - {t}_{nj}}{{t}_{ni} - {t}_{nj}} )\end{matrix}$$
wherein tₘₖ is sample time of leakage current, tₙₖ is sample time of voltage signal, Iᵢ and Vᵢ are sample values of leakage current and voltage signal at time tₘᵢ and tₙᵢ respectively, and tₘᵢ and tₙᵢ are sample times of sample points before and after the sample time of leakage current tₘₖ and the sample time of voltage signal tₙₖ respectively, hereinto i=0,1,2.

3. The monitoring method of arrester applied to smart substation of claim 1, wherein computational formulas of real and imaginary part information of the resample values of the leakage current and the SV voltage signals through the Fourier transform are:
the formula of the real part information:
$$U re = {\sum }_{i = 0}^{N - 1} U [ i ] * Hc [ j ] j = Number * i$$
the formula of the imaginary part information:
$$U im = {\sum }_{i = 0}^{N - 1} U [ i ] * Hs [ j ] j = {Number}^{*} i$$
$$Hc [ j ] = \frac{2}{N} * cos \frac{2 ( j + 1 ) π}{N} , j = 0 , 1 , … , N - 1$$
$$Hs [ j ] = \frac{2}{N} * sin \frac{2 ( j + 1 ) π}{N} , j = 0 , 1 , … , N - 1$$
wherein U(i) are sample values of appointed time window which is get from input channel number, forward cycle amount and sample indicator, N is data length, Number is harmonic order, Hc[j] and Hs[j] are filter coefficients by Fourier transforming of whole cycle.

4. The monitoring method of arrester applied to smart substation of claim 1, wherein the method of fundamental wave projection at step 4) is used with an interphase compensation fundamental wave projection method, and an definite computation process, wherein
for tripe phase arrester, it is calculated to get triple fundamental wave A, B and C amplitude values of the leakage current I_{A1}, I_{B1}, I_{C1} of triphase fundamental wave, and A, B and C amplitude values of the SV voltage signal U_{A1}, U_{B1}, U_{C1} of the triphase fundamental wave, the angles φ_{A1}, φ_{B1}, φ_{C1} between the leakage current values and the SV voltage signal of each phase of the triphase fundamental wave respectively, and angle φ_{AC1} between leakage current value of A phase of the triphase fundamental wave I_{A1} and leakage current value of C phase of the triphase fundamental wave I_{C1}. Bias angle φ=(φ_{AC1}−120)/2, so resistive current value of the A phase fundamental wave I_{RA1}=I_{A1}COS (φ_{A1}+φ), resistive current value of B phase fundamental wave I_{RB1}=I_{B1}COS(φ_{B1}), and resistive current value of the C phase fundamental wave I_{RC1}=I_{C1}COS(φ_{C1}−φ).

5. The monitoring method of arrester applied to smart substation of claim 1, wherein process of the medium filtering at step 5) is: Setting slide window with established width and sliding along time sequence, ordering data of the slide window by numeric size, and outputting the values of resistive current after medium filtered which form data sequence after medium filtering.

6. A monitoring system of arrester applied to a smart substation, comprising:
a collecting unit,
a data processing unit, and
a merge unit which transfer SV voltage signals and communicate with the data processing unit,
wherein the collecting unit is used to get the original sample values of leakage current of an arrester and an amount of lighting stroke of the arrester, and frame and transfer the original sample values of leakage current of the arrester, the data processing unit is used to analyze the original sample values of leakage current of the arrester and the Voltage signal to realize the timely diagnosing of the resistive current, and communicate with the collecting unit.

7. The monitoring system of claim 6, wherein the collecting unit comprises zero flux sensors, a rogowski coil mutual inductor, programmable amplifiers, A/D devices, a processing circuit of the amount of the lighting stroke, and a FPGA module.

8. The monitoring system of claim 6, wherein the data processing unit comprises a resample module, a compute module of the resistive current, and an analyzing and diagnosing module.

9. The monitoring system of claim 8, wherein the data processing unit further comprises an external communication module making data interaction with an integral monitor system of a smart substation by a fiber interface and in the manner of DL/T860 standard protocol.

10. The monitoring system of claim 9, wherein data is transferred on the format of FT3 between the data processing unit and the collecting unit.
